(19) United States
(12) Patent Application Publication
(10) Pub. No.: US 2025/0236507 A1
(43) Pub. Date: Jul. 24, 2025

(54) ALL-SILICON CARBIDE (SiC) ACCELERATION-PRESSURE INTEGRATED SENSOR CHIP AND PREPARATION METHOD THEREOF

(71) Applicant: XI'AN JIAOTONG UNIVERSITY, Xi'an (CN)

(72) Inventors: Xudong FANG, Xi'an (CN); Bei ZHANG, Xi'an (CN); Chen WU, Xi'an (CN); Ziyan FANG, Xi'an (CN); Zhongkai ZHANG, Xi'an (CN); Bian TIAN, Xi'an (CN)

(21) Appl. No.: 19/176,786

(22) Filed: Apr. 11, 2025

(30) Foreign Application Priority Data
Aug. 29, 2024 (CN) 202411202983.7

(51) Int. Cl. B81B 3/00; B81C 1/00

(52) U.S. Cl. CPC B81B 3/0021; B81C 1/0015; B81B 2201/0264; B81B 2203/0118; B81B 2203/0127; B81C 2201/0133; B81C 2201/0177

(57) ABSTRACT

An all-silicon carbide micro-electro-mechanical system (MEMS) acceleration-pressure integrated sensor chip includes a first patterned silicon carbide plate, a MEMS acceleration sensor chip, a second patterned silicon carbide plate, a MEMS pressure sensor chip and a third patterned silicon carbide plate fixedly connected in sequence. The MEMS acceleration sensor chip has an eight-beam and five-mass-block structure. The MEMS pressure sensor chip includes an arc-shaped cross beam and four circular diaphragms. A method for preparing the integrated sensor chip is also provided.

### CROSS-REFERENCE TO RELATED APPLICATIONS

This application claims the benefit of priority from Chinese Patent Application No. 202411202983.7, filed on Aug. 29, 2024. The content of the aforementioned application, including any intervening amendments made thereto, is incorporated herein by reference in its entirety.

### TECHNICAL FIELD

This application relates to micro-electro-mechanical system (MEMS) sensors, and more particularly to an all-silicon carbide (SiC) acceleration-pressure integrated sensor chip and a preparation method thereof.

### BACKGROUND

Micro-electro-mechanical system (MEMS) acceleration sensor chips and MEMS pressure sensor chips have been widely applied across various fields. Silicon-based materials are traditionally used for the sensor preparation and processing, but these silicon devices' operation temperature is limited to 200° C. or below. The emergence of the third-generation wide-bandgap semiconductor materials (e.g., silicon carbide) has promoted the application of MEMS sensors in harsh environments. Piezoresistive sensors have been widely popularized due to their simple working principle and excellent output performance. However, in some practical measurement scenarios, e.g., aero-engines involving high temperature, strong vibration and intense impact, the pressure measurement is easily susceptible to acceleration. In view of this, a combination of two types of sensors is often employed to achieve more accurate single-parameter measurements. In the aerospace field, it is essential to precisely control the gas or liquid pressure variation in critical components, and thus the minor pressure changes are also needed to be accurately measured. In order to enhance the measurement precision, the sensing structure is often provided with a stress-strain amplification structure for amplifying the small resistance changes in varistors.

For most of the existing acceleration-pressure integrated sensor chips, the acceleration sensor chip and the pressure sensor chip are integrated on the same substrate material. For example, Chinese patent application No. 202310610556.1 discloses a method for achieving the monolithic integration of pressure and acceleration sensor chips, in which a wing-shaped diaphragm is provided on one side of a silicon substrate and a single-beam mass-block structure is provided on the other side. Though this design reduces the size of the integrated sensor chip, its structural limitation weakens the measurement sensitivity and range. In the practical applications, high sensitivity enables the sensor chip to respond to weak signals and achieve accurate measurement and monitoring of target parameters. Additionally, a wide measurement range can effectively prevent failure caused by transient overloads and expand its application scope.

### SUMMARY

An object of the disclosure is to provide an all-silicon carbide (SiC) acceleration-pressure integrated sensor chip with enhanced sensitivity and a preparation method thereof.

Technical solutions of the present disclosure are described as follows.

In a first aspect, this application provides an all-silicon carbide acceleration-pressure integrated sensor chip, comprising:
a micro-electro-mechanical system (MEMS) acceleration sensor chip;
a first silicon carbide plate; and
a MEMS pressure sensor chip;
wherein the MEMS acceleration sensor chip, the first silicon carbide plate and the MEMS pressure sensor chip are fixedly connected in sequence;
the MEMS acceleration sensor chip comprises a multi-cantilever structure and an outer frame; the multi-cantilever structure comprises a first mass block located at a center of the multi-cantilever structure;
the first mass block has N side walls respectively fixedly connected to first ends of N first support beams, wherein N≥2; second ends of the N first support beams are respectively fixedly connected to first ends of N second mass blocks; the N second mass blocks are configured to surround the first mass block; second ends of the N second mass blocks are respectively fixedly connected to first ends of N second support beams, and second ends of the N second support beams are respectively fixedly connected to inner side walls of the outer frame; and
areas of upper surfaces of the N first support beams close to the second ends of the N first support beams are respectively provided with first piezoresistive strips; and the first piezoresistive strips are connected through a first metal ohmic contact circuit.

In some embodiments, the MEMS pressure sensor chip comprises an arc-shaped cross beam and four circular pressure-sensitive diaphragms;
the four circular pressure-sensitive diaphragms are symmetrically distributed with respect to the arc-shaped cross beam; and
a beam portion of the arc-shaped cross beam between any adjacent two of the four circular pressure-sensitive diaphragms is provided with a second piezoresistive strip; and second piezoresistive strips are connected through a second metal ohmic contact circuit.

In some embodiments, a center point of the first mass block is configured to be collinear with an axis of each of the N first support beams; and/or
a center point of each of the N second mass block is configured to be collinear with an axis of one of the N second support beams connected thereto.

In some embodiments, a top of the MEMS acceleration sensor chip is fixedly connected to a second silicon carbide plate; and the second silicon carbide plate is provided with a through-hole, and the through-hole is located directly above the first metal ohmic contact circuit.

In some embodiments, a side of the second silicon carbide plate connected to the MEMS acceleration sensor chip is provided with a groove.

In some embodiments, a bottom of the MEMS pressure sensor chip is fixedly connected to a third silicon carbide plate, and the third silicon carbide plate is provided with a pressure-sensing channel.

In some embodiments, the third silicon carbide plate is provided with a through-hole, and the through-hole is located directly below the second metal ohmic contact circuit.

In some embodiments, a side of the first silicon carbide plate connected to the MEMS acceleration sensor chip is provided with a groove.

In a second aspect, this application provides a method for preparing the all-silicon carbide acceleration-pressure integrated sensor chip provided herein, comprising:
(1) preparing the MEMS acceleration sensor chip, the first silicon carbide plate and the MEMS pressure sensor chip;
wherein the MEMS acceleration sensor chip is prepared through steps of:
(A1) processing a first N-type silicon carbide wafer to prepare a first silicon carbide substrate;
(A2) epitaxially forming a P-type silicon carbide layer on a first side of the first silicon carbide substrate; epitaxially forming a first N-type silicon carbide layer on the P-type silicon carbide layer; and forming the first piezoresistive strips by etching on areas of the first N-type silicon carbide layer respectively corresponding to the second ends of the N first support beams;
(A3) depositing a first silicon dioxide insulation layer on the first side of the first silicon carbide substrate by thermal oxidative deposition; and performing wet etching at areas of the first silicon dioxide insulation layer corresponding to the first piezoresistive strips to form wet-etched region;
(A4) sputtering a first conductive metal layer on the wet-etched region, and patterning the first conductive metal layer to obtain the first metal ohmic contact circuit; and
(A5) forming the multi-cantilever structure by etching on a second side of the first silicon carbide substrate to obtain the MEMS acceleration sensor chip;
the MEMS pressure sensor chip is prepared through steps of:
(B1) processing a second N-type silicon carbide wafer to obtain a second silicon carbide substrate;
(B2) forming the arc-shaped cross beam by etching on a first side of the second silicon carbide substrate;
(B3) epitaxially forming an insulation layer on the first side of the second silicon carbide substrate; and epitaxially forming a second N-type silicon carbide layer on the insulation layer;
(B4) forming four second piezoresistive strips by etching on the second N-type silicon carbide layer;
(B5) depositing a second silicon dioxide insulation layer on the first side of the second silicon carbide substrate by thermal oxidative deposition;
(B6) sputtering a second conductive metal layer on the second silicon dioxide insulation layer; and patterning the second conductive metal layer to obtain a second metal ohmic contact circuit; and
(B7) performing inductively coupled plasma (ICP) etching on a second side of the second silicon carbide substrate to form a back cavity and four circular pressure-sensitive diaphragms, so as to obtain the MEMS pressure sensor chip; and
(2) aligning the MEMS acceleration sensor chip, the first silicon carbide plate and the MEMS pressure sensor chip in sequence followed by adhesive bonding and curing to obtain the all-silicon carbide MEMS acceleration-pressure integrated sensor chip.

In some embodiments, the step (1) further comprises:
preparing a second silicon carbide plate and a third silicon carbide plate; and
the step (2) further comprises:
aligning the second silicon carbide plate, the MEMS acceleration sensor chip, the first silicon carbide plate, the MEMS pressure sensor chip and the third silicon carbide plate in sequence followed by adhesive bonding and curing to obtain the all-silicon carbide MEMS acceleration-pressure integrated sensor chip.

Compared to the prior art, the present disclosure has the following beneficial effects.

The present disclosure integrates a silicon carbide-based MEMS acceleration sensor chip and a silicon carbide-based MEMS pressure sensor chip in a vertical direction to obtain an acceleration-pressure integrated MEMS sensor chip. The silicon carbide material can enhance the measurement performance of the integrated sensor chip in harsh environments (e.g., high temperature), allowing for high reliability.

The MEMS acceleration sensor chip provided herein has a multi-cantilever structure composed of eight beams and five mass blocks. Both the first mass block and the second mass blocks will undergo deformation when encountering the external impact; and further, the deformation of the first mass block will cause the first support beam to deform, and the deformation of the second support beams induced by the second mass blocks will also act on the first support beam, thereby amplifying the deformation of the first support beam. The increased deformation of the cantilever beams results in a greater change in the resistance of the piezoresistive strips positioned at the second end of the first support beam, thereby enhancing the sensor's sensitivity.

The MEMS pressure sensor chip disclosed herein has an arc-shaped cross beam structure with four circular pressure-sensitive diaphragms. When subjected to external pressure, two adjacent circular pressure-sensitive diaphragms deform simultaneously, causing the second piezoresistive strip positioned on the beam portion therebetween to exhibit greater resistance changes, thereby improving the sensor's sensitivity.

Moreover, the first silicon carbide plate is provided between the MEMS acceleration sensor chip and the MEMS pressure sensor chip to isolate the two sensors from each other to prevent mutual interference. The first silicon carbide plate also provides a sealed pressure reference cavity for the MEMS pressure sensor chip, enabling the absolute pressure measurement and improving the sensor's measurement accuracy. Additionally, the first silicon carbide plate also plays a role in limiting the movement of the MEMS pressure sensor chip.

Moreover, the second silicon carbide plate is provided above the MEMS acceleration sensor chip to protect the sensitive structure of the MEMS acceleration sensor chip and limit the movement of the MEMS acceleration sensor chip.

Further, the third silicon carbide plate is provided below the MEMS pressure sensor chip to protect the beam-diaphragm structure and prevent the sensitive structure from being exposed to the environmental media.

Further, the second silicon carbide plate and the first silicon carbide plate are each provided with a groove, which offers space for vibrational displacement generated by the mass blocks on the MEMS acceleration sensor chip when subjected to external impact.

### BRIEF DESCRIPTION OF THE DRAWINGS

FIG. 1 schematically illustrates a three-dimensional stacking structure of an all-silicon carbide micro-electro-mechanical system (MEMS) acceleration-pressure integrated sensor chip according to an embodiment of the present disclosure;

FIG. 2 is an isometric sectional view of the all-silicon carbide MEMS acceleration-pressure integrated sensor chip according to an embodiment of the present disclosure;

FIG. 3 is a front view of a silicon carbide-based MEMS acceleration sensor chip according to an embodiment of the present disclosure; and

FIG. 4 is a front view of a silicon carbide-based MEMS pressure sensor chip according to an embodiment of the present disclosure.

In the figures: 100—first silicon carbide plate; 101—first through-hole; 102—first groove; 200—micro-electro-mechanical system (MEMS) acceleration sensor chip; 201—first mass block; 202—first support beam; 203—second support beam; 204—first piezoresistive strip; 205—first metal ohmic contact circuit; 206—outer frame; 207—second mass block; 300—second silicon carbide plate; 301—second groove; 400—MEMS pressure sensor chip; 401—back cavity; 402—pressure-sensitive diaphragm; 403—second metal ohmic contact circuit; 404—second piezoresistive strip; 405—arc-shaped cross beam; 500—third silicon carbide plate; 501—second through-hole; and 502—pressure-sensing channel.

### DETAILED DESCRIPTION OF EMBODIMENTS

The technical solutions of the present disclosure will be described in further detail below with reference to the accompanying drawings and embodiments.

To make those skilled in the art better understand the technical solutions of the present disclosure, the technical solutions will be described clearly and completely below in conjunction with the accompanying drawings. It is obvious that described below are merely some embodiments of the present disclosure, instead of all embodiments. Based on the embodiments in the present disclosure, all other embodiments obtained by those of ordinary skill in the art without making creative effort shall fall within the scope of the present disclosure defined by the appended claims.

It should be noted that when a component is described as being “provided on” another component, it may be directly arranged on another component or indirectly arranged on another component through an intermediate component. Similarly, when a component is described as being “connected to” another component, it may be directly connected to another component or indirectly connected with another component through an intermediate component. As used herein, the orientation or positional relationships terms, such as “up”, “down”, “front”, “back”, “left”, “right”, “top”, “bottom”, “inner” and “outer” are based on the those shown in the accompanying drawings. These terms are solely for the convenience of describing the present disclosure in a simplified manner, and are not intended to indicate or imply that the devices or components must have specific orientations or be constructed and operated in such orientations. Therefore, these terms should not be understood as limitations of the present disclosure.

Unless otherwise defined, all technical and scientific terms used in the present disclosure have the same meaning as commonly understood by those of ordinary skill in the art. The terms used herein are merely descriptive, and are not intended to limit the disclosure. As used herein, the term “and/or” refers to any and all combinations of one or more of the listed items.

The all-silicon carbide (SiC) micro-electro-mechanical system (MEMS) acceleration-pressure integrated sensor chip provided herein can achieve the high-sensitivity and wide-range measurement of acceleration and pressure signals in harsh environments (e.g., high temperature). A measurement unit of the integrated sensor chip includes a MEMS acceleration sensor chip and a MEMS pressure sensor chip that are vertically interconnected.

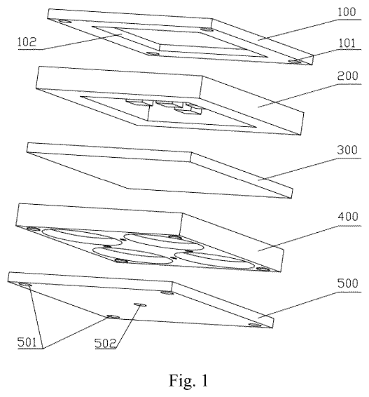

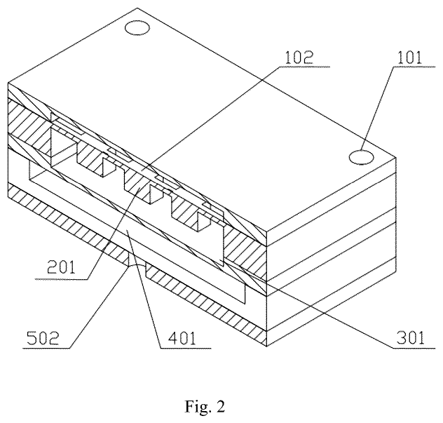

As shown in FIGS. 1-2, an embodiment of the present application provides an all-silicon carbide acceleration-pressure integrated sensor chip, including a first silicon carbide plate 100, a MEMS acceleration sensor chip 200, a second silicon carbide plate 300, a MEMS pressure sensor chip 400 and a third silicon carbide plate 500 aligned in sequence. The MEMS acceleration sensor chip 200 is arranged above the MEMS pressure sensor chip 400. The MEMS pressure sensor chip 400 is arranged in an inverted orientation.

The first silicon carbide plate 100, the second silicon carbide plate 300 and the third silicon carbide plate 500 are patterned silicon carbide plates.

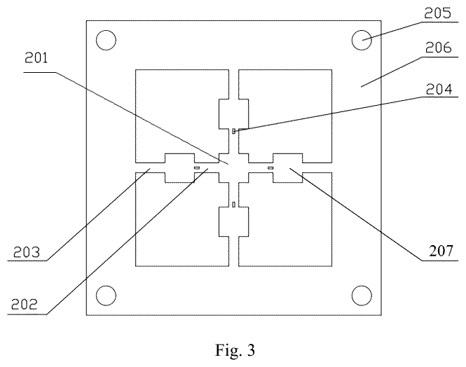

As shown in FIGS. 2-3, the MEMS acceleration sensor chip 200 includes a multi-cantilever structure and an outer frame 206 arranged above the second silicon carbide plate 300. The multi-cantilever structure includes eight cantilevers and five mass blocks. The five mass blocks include a first mass block 201 and a second mass block 207. The eight cantilevers include a first support beam 202 and a second support beam 203 according to their positions. The first mass block 201 is located at a center of the MEMS acceleration sensor chip 200. The first mass block 201 has four side walls respectively fixedly connected to first ends of four first support beams 202. Second ends of the four first support beams 202 are respectively fixedly connected to first ends of four second mass blocks 207. The four second mass blocks 207 are configured to surround the first mass block 201. Second ends of the four second mass blocks 207 are respectively fixedly connected to first ends of four second support beams 203, and second ends of the four second support beams 203 are respectively fixedly connected to four inner side walls of the outer frame 206.

A space outside the connection between the cantilevers and the mass blocks is configured as a cavity. Areas of upper surfaces of the four first support beams 202 close to the second ends of the four first support beams are respectively provided with first piezoresistive strips 204, and the first piezoresistive strips 204 are connected through a first metal ohmic contact circuit 205.

The four first support beams 202 of the MEMS acceleration sensor chip 200 have equal lengths. Similarly, the four second support beams 203 also have equal lengths.

A center point of any mass block in the MEMS acceleration sensor chip 200 is collinear with a center point of the cantilever connected thereto, and an axis of the any mass block is parallel to an axis of the cantilever connected thereto.

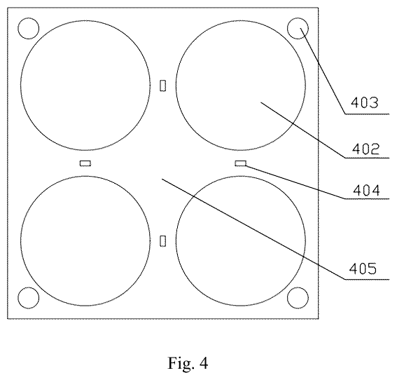

As shown in FIGS. 2 and 4, the MEMS pressure sensor chip 400 includes an arc-shaped cross beam 405 and four circular pressure-sensitive diaphragms 402. The arc-shaped cross beam 405 and the circular pressure-sensitive diaphragms 402 are arranged below the second silicon carbide plate 300. The four circular pressure-sensitive diaphragms 402 are symmetrically distributed with respect to the arc-shaped cross beam 405. Abeam portion of the arc-shaped cross beam 405 between any adjacent two of the four circular pressure-sensitive diaphragms 402 in the same direction is provided with a second piezoresistive strip 404. Second piezoresistive strips 404 are connected through a second metal ohmic contact circuit 403.

The second silicon carbide plate 300 is provided between the MEMS acceleration sensor chip 200 and the MEMS pressure sensor chip 400. A side of the second silicon carbide plate 300 connected to the MEMS acceleration sensor chip 200 is provided with a second groove 301.

The first silicon carbide plate 100 is provided above the MEMS acceleration sensor chip 200. The first silicon carbide plate 100 corresponding to the first metal ohmic contact circuits 205 is provided with four vertically oriented first through-holes 101, and the four first through-holes 101 are symmetrically distributed. Each first through-hole 101 is configured to facilitate subsequent signal transmission. A side of the first silicon carbide plate 100 connected to the MEMS acceleration sensor chip 200 is provided with a first groove 102.

The third silicon carbide plate 500 is provided below the MEMS pressure sensor chip 400. The third silicon carbide plate 500 corresponding to the second metal ohmic contact circuits 403 is provided with four vertically oriented second through-holes 501, and the four second through-holes 501 are symmetrically distributed. Each second through-hole 501 is configured to facilitate subsequent signal transmission. A center of the third silicon carbide plate 500 is provided with a central through-hole configured as a pressure-sensing channel 502 of the MEMS pressure sensor chip 400.

A center point of each second piezoresistive strip 404 is located on a connection line between centers of any adjacent two circular diaphragms 402. Each side of the second piezoresistive strip 404 is parallel to a substrate of the MEMS pressure sensor chip 400.

The first groove 102 provided on the first silicon carbide plate 100 and the second groove 301 provided on the second silicon carbide plate 300 have equal side lengths. The first groove 102 and the second groove 301 are each equidistant from two parallel inner sides walls of the outer frame 206.

The pressure-sensing channel 502 is located at a center of the third silicon carbide plate 500.

The first through-holes 101 on the first silicon carbide plate 100 are respectively aligned with centers of the first metal ohmic contact circuits 205. The second through-holes 501 on the third silicon carbide plate 500 are respectively aligned with centers of the second metal ohmic contact circuits 403.

The MEMS acceleration sensor chip 200 and the MEMS pressure sensor chip 400 are vertically aligned.

The above all-silicon carbide acceleration-pressure integrated sensor chip is prepared as follows.
Step (1) Preparation of the first silicon carbide plate 100
Step (1.1) A first silicon carbide wafer is thinned.
Step (1.2) The first silicon carbide wafer is subjected to laser processing to form the first through-hole 101.
Step (1.3) A front side of the first silicon carbide wafer is etched to form the first groove 102.
Step (1.4) The front side of the first silicon carbide wafer is subjected to thermal oxidation to obtain a first insulation layer, so as to obtain the first silicon carbide plate 100.
Step (2) Preparation of the MEMS acceleration sensor chip 200
Step (2.1) A first N-type silicon carbide wafer is processed to form a first silicon carbide substrate.
Step (2.2) A P-type silicon carbide layer is epitaxially formed on a front side of the first silicon carbide substrate. A first N-type silicon carbide layer is epitaxially formed on the P-type silicon carbide layer. The first piezoresistive strips 204 are formed by etching on areas of the first N-type silicon carbide layer respectively corresponding to the second end of the first support beam 202.
Step (2.3) A first silicon dioxide insulation layer is deposited on the front side of the first silicon carbide substrate by thermal oxidative deposition.
Step (2.4) Wet etching is performed at areas of the first silicon dioxide insulation layer corresponding to the first piezoresistive strips 204 to form a wet-etched region.
Step (2.5) A first conductive metal layer is sputtered on the wet-etched region, followed by patterning and annealing at a high-temperature of 800-900° C. for 2-8 min to obtain the first metal ohmic contact circuit 205.
Step (2.6) A back side of the first silicon carbide substrate is subjected to inductively coupled plasma (ICP) etching to form the multi-cantilever structure, resulting in the MEMS acceleration sensor chip.
Step (3) Preparation of the second silicon carbide plate 300
Step (3.1) A second silicon carbide wafer is thinned.
Step (3.2) A front side of the second silicon carbide wafer is etched to form the second groove 301.
Step (3.3) A second insulation layer is deposited on the front side of the second silicon carbide wafer by thermal oxidative deposition, so as to obtain the second silicon carbide plate 300.
Step (4) Preparation of the MEMS pressure sensor chip 400
Step (4.1) A second N-type silicon carbide wafer is processed to form a second silicon carbide substrate.
Step (4.2) A front side of the second silicon carbide substrate is subjected to ICP etching to form the arc-shaped cross beam 405.
Step (4.3) A third insulation layer is epitaxially formed on the front side of the second silicon carbide substrate. A second N-type silicon carbide layer is epitaxially formed on the third insulation layer.
Step (4.4) The second N-type silicon carbide layer is etched to form four second piezoresistive strips 404.
Step (4.5) A second silicon dioxide insulation layer is deposited on the front side of the second silicon carbide substrate by thermal oxidative deposition.
Step (4.6) A second conductive metal layer is sputtered on the second silicon dioxide insulation layer, followed by patterning and annealing at a high-temperature of 800-900° C. to obtain the second metal ohmic contact circuit 403.
Step (4.7) A back side of the second silicon carbide substrate is subjected to ICP etching to form a back cavity 401 and a pressure-sensitive diaphragm 402, so as to obtain the MEMS pressure sensor chip 400.
Step (5) Preparation of the third silicon carbide plate 500
Step (5.1) A third silicon carbide wafer is thinned.
Step (5.2) The third silicon carbide wafer is subjected to laser processing to form the second through-hole 501.
Step (5.3) A four insulation layer is deposited on a front side of the third silicon carbide wafer by thermal oxidative deposition, so as to obtain the third silicon carbide plate 500.
Step (6) Preparation of the integrated sensor chip
Step (6.1) The first silicon carbide plate 100, the silicon carbide MEMS acceleration sensor chip 200, the second silicon carbide plate 300, the silicon carbide MEMS pressure sensor chip 400 and the third silicon carbide plate 500 are aligned and adhesively attached in a designed sequence using a high-temperature-resistant insulation adhesive, so as to obtain a preliminarily assembled structure.
Step (6.2) The preliminarily assembled structure is subjected to curing at a temperature of 150-200° C. for 2-3 h to obtain the desired all-silicon carbide MEMS acceleration-pressure integrated sensor chip.

In some embodiments, some processes can be carried out simultaneously to improve preparation efficiency and enable batch processing. For example, the first silicon carbide plate 100, the second silicon carbide plate 300 and the third silicon carbide plate 500 can be processed in separate regions on the same large-size silicon carbide wafer. The processing steps include thinning, through-hole preparation, etching, thermal oxidative deposition and dicing to obtain individual silicon carbide plates.

The embodiments of the present disclosure are described in detail below to facilitate understanding of the technical solutions. It should be noted that described herein are merely preferred embodiments, rather than all embodiments of the present disclosure.

### Example 1

Provided herein was a method for preparing an all-silicon carbide micro-electro-mechanical system (MEMS) acceleration-pressure integrated sensor chip, which was performed as follows.
Step (1) A 3 mm×3 mm N-type silicon carbide wafer A with a thickness of 350 μm was cleaned using acetone, ethanol and deionized water to remove organic and fine solid particle, and dried.
Step (2) Two homogeneous epitaxial layers were grown on a Si surface of the N-type silicon carbide wafer A obtained in step (1). Specifically, for the first epitaxial growth, a P-type epitaxial layer was grown in an atmosphere of silane, propane and trimethylaluminum with aluminum selected as a dopant ion; and for the second epitaxial growth, an N-type epitaxial layer was grown on the P-type epitaxial layer in an atmosphere of silane, propane and nitrogen gas with nitrogen selected as the dopant ion. The P-type epitaxial layer and the N-type epitaxial layer each had a thickness of 2 μm.
Step (3) The N-type epitaxial layer was subjected to shallow reactive-ion etching (RIE) to obtain four first piezoresistive strips 204 respectively located on four first support beams 202, where the first piezoresistive strips 204 can be each designed to be 50 μm in length, 20 μm in width and 3 μm in thickness.
Step (4) A front side of the silicon carbide wafer A obtained in step (3) was calcined at 600° C. for 2 h in an air atmosphere for thermal oxidation to obtain a SiO₂ layer with a thickness of 100 nm.
Step (5) The front side of the silicon carbide wafer A obtained in step (4) was coated with a photoresist and patterned. The SiO₂ layer was subjected to wet etching in hydrofluoric acid (HF) to obtain an ohmic contact window, followed by photoresist removal and cleaning.
Step (6) A metal layer was sputtered onto the front side of the silicon carbide wafer A obtained in step (5), patterned by wet etching (a portion of the metal layer corresponding to the ohmic contact window was retained), and annealed at 800° C. for 8 min to obtain a first metal ohmic contact circuit 205.
Step (7) Aback side of the silicon carbide wafer A was subjected to inductively coupled plasma (ICP) etching to obtain a cantilever beam structure and mass blocks. The etching could be first performed according to a thickness of the mass block (e.g., a thickness of 100 μm), and then performed according to position of the cantilever beam. Considering the relatively-large etching depth required, the etching could be performed in two steps, with each reaching an etching depth of 100 μm to obtain the cantilever beam and the mass blocks, so as to obtain a MEMS acceleration sensor chip 200.
Step (8) Another 3 mm×3 mm N-type silicon carbide wafer B with a thickness of 350 μm was processed according to step (1).
Step (9) A front side of the silicon carbide wafer B was treated according to steps (2)-(6) to form a second piezoresistive strip 404 and a second metal ohmic contact circuit 403, where the second piezoresistive strip 404 can be 100 μm in length, 50 μm in width and 3 μm in thickness.
Step (10) A front side of the silicon carbide wafer B was subjected to ICP etching to obtain an arc-shaped cross beam structure 405 with an etching depth of 100 μm.
Step (11) Aback side of the silicon carbide wafer B was subjected to ICP deep etching to form a back cavity 401 with an etching depth of 200 μm, and four pressure-sensitive diaphragms 402 each having a thickness of 50 μm were formed, so as to obtain a MEMS pressure sensor chip 400.
Step (12) Three 3 mm×3 mm N-type silicon carbide wafers (designated as silicon carbide wafer C, silicon carbide wafer D and silicon carbide wafer E) each with a thickness of 350 μm were thinned to 150 μm and then processed according to step (1).
Step (13) The silicon carbide wafer C and the silicon carbide wafer D were aligned, stacked, and processed with femtosecond laser to form a first through-hole 101 and a second through-hole 501 at a position corresponding to the ohmic contact window, where the first through-hole 101 and the second through-hole 501 each had a diameter of 200 μm. A pressure-sensing channel 502 with a diameter of 200 μm was formed at a center of the silicon carbide wafer D.
Step (14) A front side of the silicon carbide wafer C was subjected to ICP shallow etching to obtain a first groove 102 in a square shape. A front side of the silicon carbide wafer E was subjected to ICP shallow etching to obtain a second groove 301 in a square shape. The first groove 102 had a side length of 2 mm and a depth of 100 μm. The second groove 301 had a side length of 2 mm and a depth of 100 μm.
Step (15) The silicon carbide wafer C, the silicon carbide wafer D and the silicon carbide wafer E processed in step (14) were treated according to step (4).
Step (16) The silicon carbide wafers A-E were adhesively bonded by using a high-temperature adhesive in a designed sequence, and cured at 150° C. for 3 h to obtain the desired all-silicon carbide MEMS acceleration-pressure integrated sensor chip.

### Example 2

Provided herein was a method for preparing an all-silicon carbide micro-electro-mechanical system (MEMS) acceleration-pressure integrated sensor chip, which was performed as follows.
Step (1) A 3 mm×3 mm N-type silicon carbide wafer A with a thickness of 350 μm was cleaned using acetone, ethanol and deionized water to remove organic and fine solid particle, and dried.
Step (2) Two homogeneous epitaxial layers were grown on a Si surface of the N-type silicon carbide wafer A obtained in step (1). Specifically, for the first epitaxial growth, a P-type epitaxial layer was grown in an atmosphere of silane, propane and trimethylaluminum with aluminum selected as a dopant ion; and for the second epitaxial growth, an N-type epitaxial layer was grown on the P-type epitaxial layer in an atmosphere of silane, propane and nitrogen gas with nitrogen selected as the dopant ion. The P-type epitaxial layer and the N-type epitaxial layer each had a thickness of 2 μm.
Step (3) The N-type epitaxial layer was subjected to shallow reactive-ion etching (RIE) to obtain four first piezoresistive strips 204 respectively located on four first support beams 202, where the first piezoresistive strips 204 can be each designed to be 50 μm in length, 20 μm in width and 3 μm in thickness.
Step (4) A front side of the silicon carbide wafer A obtained in step (3) was calcined at 600° C. for 2 h in an air atmosphere for thermal oxidation to obtain a SiO₂ layer with a thickness of 100 nm.
Step (5) The front side of the silicon carbide wafer A obtained in step (4) was coated with a photoresist and patterned. The SiO₂ layer was subjected to wet etching in hydrofluoric acid (HF) to obtain an ohmic contact window, followed by photoresist removal and cleaning.
Step (6) A metal layer was sputtered onto the front side of the silicon carbide wafer A obtained in step (5), patterned by wet etching (a portion of the metal layer corresponding to the ohmic contact window was retained), and annealed at 850° C. for 5 min to obtain a first metal ohmic contact circuit 205.
Step (7) Aback side of the silicon carbide wafer A was subjected to inductively coupled plasma (ICP) etching to obtain a cantilever beam structure and mass blocks. The etching could be first performed according to a thickness of the mass block (e.g., a thickness of 100 μm), and then performed according to position of the cantilever beam. Considering the relatively-large etching depth required, the etching could be performed in two steps, with each reaching an etching depth of 100 μm to obtain the cantilever beam and the mass blocks, so as to obtain a MEMS acceleration sensor chip 200.
Step (8) Another 3 mm×3 mm N-type silicon carbide wafer B with a thickness of 350 μm was processed according to step (1).
Step (9) A front side of the silicon carbide wafer B was treated according to steps (2)-(6) to form a second piezoresistive strip 404 and a second metal ohmic contact circuit 403, where the second piezoresistive strip 404 can be 100 μm in length, 50 μm in width and 3 μm in thickness.
Step (10) A front side of the silicon carbide wafer B was subjected to ICP etching to obtain an arc-shaped cross beam structure 405 with an etching depth of 100 μm.
Step (11) Aback side of the silicon carbide wafer B was subjected to ICP deep etching to form a back cavity 401 with an etching depth of 200 μm, and four pressure-sensitive diaphragms 402 each having a thickness of 50 μm were formed, so as to obtain a MEMS pressure sensor chip 400.
Step (12) Three 3 mm×3 mm N-type silicon carbide wafers (designated as silicon carbide wafer C, silicon carbide wafer D and silicon carbide wafer E) each with a thickness of 350 μm were thinned to 150 μm and then processed according to step (1).
Step (13) The silicon carbide wafer C and the silicon carbide wafer D were aligned, stacked, and processed with femtosecond laser to form a first through-hole 101 and a second through-hole 501 at a position corresponding to the ohmic contact window, where the first through-hole 101 and the second through-hole 501 each had a diameter of 200 μm. A pressure-sensing channel 502 with a diameter of 200 μm was formed at a center of the silicon carbide wafer D.
Step (14) A front side of the silicon carbide wafer C was subjected to ICP shallow etching to obtain a first groove 102 in a square shape. A front side of the silicon carbide wafer E was subjected to ICP shallow etching to obtain a second groove 301 in a square shape. The first groove 102 had a side length of 2 mm and a depth of 100 μm. The second groove 301 had a side length of 2 mm and a depth of 100 μm.
Step (15) The silicon carbide wafer C, the silicon carbide wafer D and the silicon carbide wafer E processed in step (14) were treated according to step (4).
Step (16) The silicon carbide wafers A-E were adhesively bonded by using a high-temperature adhesive in a designed sequence, and cured at 175° C. for 2.5 h to obtain the desired all-silicon carbide MEMS acceleration-pressure integrated sensor chip.

### Example 3

Provided herein was a method for preparing an all-silicon carbide micro-electro-mechanical system (MEMS) acceleration-pressure integrated sensor chip, which was performed as follows.
Step (1) A 3 mm×3 mm N-type silicon carbide wafer A with a thickness of 350 μm was cleaned using acetone, ethanol and deionized water to remove organic and fine solid particle, and dried.
Step (2) Two homogeneous epitaxial layers were grown on a Si surface of the N-type silicon carbide wafer A obtained in step (1). Specifically, for the first epitaxial growth, a P-type epitaxial layer was grown in an atmosphere of silane, propane and trimethylaluminum with aluminum selected as a dopant ion; and for the second epitaxial growth, an N-type epitaxial layer was grown on the P-type epitaxial layer in an atmosphere of silane, propane and nitrogen gas with nitrogen selected as the dopant ion. The P-type epitaxial layer and the N-type epitaxial layer each had a thickness of 2 μm.
Step (3) The N-type epitaxial layer was subjected to shallow reactive-ion etching (RIE) to obtain four first piezoresistive strips 204 respectively located on four first support beams 202, where the first piezoresistive strips 204 can be each designed to be 50 μm in length, 20 μm in width and 3 μm in thickness.
Step (4) A front side of the silicon carbide wafer A obtained in step (3) was calcined at 600° C. for 2 h in an air atmosphere for thermal oxidation to obtain a SiO₂ layer with a thickness of 100 nm.
Step (5) The front side of the silicon carbide wafer A obtained in step (4) was coated with a photoresist and patterned. The SiO₂ layer was subjected to wet etching in hydrofluoric acid (HF) to obtain an ohmic contact window, followed by photoresist removal and cleaning.
Step (6) A metal layer was sputtered onto the front side of the silicon carbide wafer A obtained in step (5), patterned by wet etching (a portion of the metal layer corresponding to the ohmic contact window was retained), and annealed at 900° C. for 2 min to obtain a first metal ohmic contact circuit 205.
Step (7) Aback side of the silicon carbide wafer A was subjected to inductively coupled plasma (ICP) etching to obtain a cantilever beam structure and mass blocks. The etching could be first performed according to a thickness of the mass block (e.g., a thickness of 100 μm), and then performed according to position of the cantilever beam. Considering the relatively-large etching depth required, the etching could be performed in two steps, with each reaching an etching depth of 100 μm to obtain the cantilever beam and the mass blocks, so as to obtain a MEMS acceleration sensor chip 200.
Step (8) Another 3 mm×3 mm N-type silicon carbide wafer B with a thickness of 350 μm was processed according to step (1).
Step (9) A front side of the silicon carbide wafer B was treated according to steps (2)-(6) to form a second piezoresistive strip 404 and a second metal ohmic contact circuit 403, where the second piezoresistive strip 404 can be 100 μm in length, 50 μm in width and 3 μm in thickness.
Step (10) A front side of the silicon carbide wafer B was subjected to ICP etching to obtain an arc-shaped cross beam structure 405 with an etching depth of 100 μm.
Step (11) Aback side of the silicon carbide wafer B was subjected to ICP deep etching to form a back cavity 401 with an etching depth of 200 μm, and four pressure-sensitive diaphragms 402 each having a thickness of 50 μm were formed, so as to obtain a MEMS pressure sensor chip 400.
Step (12) Three 3 mm×3 mm N-type silicon carbide wafers (designated as silicon carbide wafer C, silicon carbide wafer D and silicon carbide wafer E) each with a thickness of 350 μm were thinned to 150 μm and then processed according to step (1).
Step (13) The silicon carbide wafer C and the silicon carbide wafer D were aligned, stacked, and processed with femtosecond laser to form a first through-hole 101 and a second through-hole 501 at a position corresponding to the ohmic contact window, where the first through-hole 101 and the second through-hole 501 each had a diameter of 200 μm. A pressure-sensing channel 502 with a diameter of 200 μm was formed at a center of the silicon carbide wafer D.
Step (14) A front side of the silicon carbide wafer C was subjected to ICP shallow etching to obtain a first groove 102 in a square shape. A front side of the silicon carbide wafer E was subjected to ICP shallow etching to obtain a second groove 301 in a square shape. The first groove 102 had a side length of 2 mm and a depth of 100 μm. The second groove 301 had a side length of 2 mm and a depth of 100 μm.
Step (15) The silicon carbide wafer C, the silicon carbide wafer D and the silicon carbide wafer E processed in step (14) were treated according to step (4).
Step (16) The silicon carbide wafers A-E were adhesively bonded by using a high-temperature adhesive in a designed sequence, and cured at 200° C. for 2 h to obtain the desired all-silicon carbide MEMS acceleration-pressure integrated sensor chip.

As used herein, the term “composed of” is intended to include the specified elements, components, parts, or steps, as well as any additional elements, components, parts, or steps that do not substantially alter the essential novelty of the combination. As used herein, the terms “comprise” and “include” are intended to include combinations of the specified elements, components, parts, or steps, as well as embodiments that are essentially composed of these elements, components, parts, or steps. As used herein, the term “can” is intended to indicate that any described attributes are optional.

Multiple elements, components, parts or steps may be provided by a single integrated element, component, part, or step. Alternatively, a single integrated element, component, part, or step may be divided into multiple separate elements, components, parts or steps. As used herein, the terms “a” and “an” used to describe an element, component, part, or step are not intended to exclude other elements, components, parts or steps.

It should be noted that the described embodiments are merely illustrative, and are not intended to limit the scope of the present disclosure. It should be understood that various modifications, changes and replacements made by those skilled in the art without departing from the spirit of the disclosure shall fall within the scope of the present disclosure defined by the appended claims.

What is claimed is:

1. An all-silicon carbide acceleration-pressure integrated sensor chip, comprising:
a micro-electro-mechanical system (MEMS) acceleration sensor chip;
a first silicon carbide plate; and
a MEMS pressure sensor chip;
wherein the MEMS acceleration sensor chip, the first silicon carbide plate and the MEMS pressure sensor chip are fixedly connected in sequence;
the MEMS acceleration sensor chip comprises a multi-cantilever structure and an outer frame; the multi-cantilever structure comprises a first mass block located at a center of the multi-cantilever structure;
the first mass block has N side walls respectively fixedly connected to first ends of N first support beams, wherein N≥2; second ends of the N first support beams are respectively fixedly connected to first ends of N second mass blocks; the N second mass blocks are configured to surround the first mass block; second ends of the N second mass blocks are respectively fixedly connected to first ends of N second support beams, and second ends of the N second support beams are respectively fixedly connected to inner side walls of the outer frame; and
areas of upper surfaces of the N first support beams close to the second ends of the N first support beams are respectively provided with first piezoresistive strips; and the first piezoresistive strips are connected through a first metal ohmic contact circuit.

2. The all-silicon carbide acceleration-pressure integrated sensor chip of claim 1, wherein the MEMS pressure sensor chip comprises an arc-shaped cross beam and four circular pressure-sensitive diaphragms;
the four circular pressure-sensitive diaphragms are symmetrically distributed with respect to the arc-shaped cross beam; and
a beam portion of the arc-shaped cross beam between any adjacent two of the four circular pressure-sensitive diaphragms is provided with a second piezoresistive strip; and second piezoresistive strips are connected through a second metal ohmic contact circuit.

3. The all-silicon carbide acceleration-pressure integrated sensor chip of claim 1, wherein a center point of the first mass block is configured to be collinear with an axis of each of the N first support beams; and/or
a center point of each of the N second mass block is configured to be collinear with an axis of one of the N second support beams connected thereto.

4. The all-silicon carbide acceleration-pressure integrated sensor chip of claim 1, wherein a top of the MEMS acceleration sensor chip is fixedly connected to a second silicon carbide plate; and the second silicon carbide plate is provided with a through-hole, and the through-hole is located directly above the first metal ohmic contact circuit.

5. The all-silicon carbide acceleration-pressure integrated sensor chip of claim 4, wherein a side of the second silicon carbide plate connected to the MEMS acceleration sensor chip is provided with a groove.

6. The all-silicon carbide acceleration-pressure integrated sensor chip of claim 2, wherein a bottom of the MEMS pressure sensor chip is fixedly connected to a third silicon carbide plate, and the third silicon carbide plate is provided with a pressure-sensing channel.

7. The all-silicon carbide acceleration-pressure integrated sensor chip of claim 6, wherein the third silicon carbide plate is provided with a through-hole, and the through-hole is located directly below the second metal ohmic contact circuit.

8. The all-silicon carbide acceleration-pressure integrated sensor chip of claim 1, wherein a side of the first silicon carbide plate connected to the MEMS acceleration sensor chip is provided with a groove.

9. A method for preparing the all-silicon carbide acceleration-pressure integrated sensor chip of claim 1, comprising:
(1) preparing the MEMS acceleration sensor chip, the first silicon carbide plate and the MEMS pressure sensor chip;
wherein the MEMS acceleration sensor chip is prepared through steps of:
(A1) processing a first N-type silicon carbide wafer to prepare a first silicon carbide substrate;
(A2) epitaxially forming a P-type silicon carbide layer on a first side of the first silicon carbide substrate; epitaxially forming a first N-type silicon carbide layer on the P-type silicon carbide layer; and forming the first piezoresistive strips by etching on areas of the first N-type silicon carbide layer respectively corresponding to the second ends of the N first support beams;
(A3) depositing a first silicon dioxide insulation layer on the first side of the first silicon carbide substrate by thermal oxidative deposition; and performing wet etching at areas of the first silicon dioxide insulation layer corresponding to the first piezoresistive strips to form wet-etched region;
(A4) sputtering a first conductive metal layer on the wet-etched region, and patterning the first conductive metal layer to obtain the first metal ohmic contact circuit; and
(A5) forming the multi-cantilever structure by etching on a second side of the first silicon carbide substrate to obtain the MEMS acceleration sensor chip;
the MEMS pressure sensor chip is prepared through steps of:
(B1) processing a second N-type silicon carbide wafer to obtain a second silicon carbide substrate;
(B2) forming the arc-shaped cross beam by etching on a first side of the second silicon carbide substrate;
(B3) epitaxially forming an insulation layer on the first side of the second silicon carbide substrate; and epitaxially forming a second N-type silicon carbide layer on the insulation layer;
(B4) forming four second piezoresistive strips by etching on the second N-type silicon carbide layer;
(B5) depositing a second silicon dioxide insulation layer on the first side of the second silicon carbide substrate by thermal oxidative deposition;
(B6) sputtering a second conductive metal layer on the second silicon dioxide insulation layer; and patterning the second conductive metal layer to obtain a second metal ohmic contact circuit; and
(B7) performing inductively coupled plasma (ICP) etching on a second side of the second silicon carbide substrate to form a back cavity and four circular pressure-sensitive diaphragms, so as to obtain the MEMS pressure sensor chip; and
(2) aligning the MEMS acceleration sensor chip, the first silicon carbide plate and the MEMS pressure sensor chip in sequence followed by adhesive bonding and curing to obtain the all-silicon carbide MEMS acceleration-pressure integrated sensor chip.

10. The method of claim 9, wherein the step (1) further comprises:
preparing a second silicon carbide plate and a third silicon carbide plate; and
the step (2) further comprises:
aligning the second silicon carbide plate, the MEMS acceleration sensor chip, the first silicon carbide plate, the MEMS pressure sensor chip and the third silicon carbide plate in sequence followed by adhesive bonding and curing to obtain the all-silicon carbide MEMS acceleration-pressure integrated sensor chip.
